(19) United States
(12) Patent Application Publication
(10) Pub. No.: US 2008/0165495 A1
(43) Pub. Date: Jul. 10, 2008

(54) Electric Device Comprising a Housing and a Cooling Body

(76) Inventors: Hans-Peter Miller, Suttgart (DE); Andreas Doeffinger, Leonberg (DE); Nigel Shaw, Swansea (GB); Laura Reyes Tello, Bridgend (GB); Tim Brown, Henllys Cwmbran South Wales (GB)

Correspondence Address: MICHAEL J. STRIKER, 103 EAST NECK ROAD, HUNTINGTON, NY, 11743, US

(21) Appl. No.: 11/573,905

(22) PCT Filed: Aug. 10, 2005
(86) PCT No.: PCT/EP2005/053948

§ 371 Date: Sep. 26, 2007

(30) Foreign Application Priority Data
Aug. 21, 2004 (DE) 10 2004 040 596.4

(51) Int. Cl. H05K 7/20

(52) U.S. Cl. 361/688

(57) ABSTRACT

The invention relates to an electric device (10) comprising a housing (13) and a cooling body (16) which is secured to the housing (13). A gap (43) is arranged between the cooling body (16) and the separated housing (13), said gap comprising, at least partially a collar (31) which surrounds an opening (34), and a groove (49) which receives the collar (31). Sealing means (52), which seal the gap (43) in an at least liquid-tight manner, is arranged between the collar (31) and the groove (49).

### PRIOR ART

The invention relates to an electric device having a housing and a cooling body, and quite particularly to the mechanical connection between the cooling body and the housing. Known electric devices of this type have a cooling body which is retained in the housing as a result of the fact that the cooling body is sheathed by the injection-molding composition that forms the housing. This creates a form lock between the cooling body and the housing that leads to both a tight connection and a secure mechanical fastening. In the invention, it is contemplated that the sealing action between the cooling body and the housing be further improved.

### ADVANTAGES OF THE INVENTION

The electric device of the invention, having a housing and a cooling body and having the characteristics of the main claim, has the advantage that because of the embodiment of a seam between the cooling body and the separate housing, which seam at least partially comprises a collar surrounding an opening and a groove receiving the collar, there being a sealing means between the collar and the groove that closes the seam at least in fluid-tight fashion, excellent tightness between the housing and the cooling body is attained.

By the provisions recited in the dependent claims, advantageous refinements of the electric device of the main claim are possible. If the collar is profiled in such a way that a curvature is on a side of the collar facing away from the opening, then in cooperation with the groove and the sealing means located in it, the result is that the sealing means that is not set or has not yet set is forced somewhat away from the opening by the collar, and there is accordingly not the risk that too much sealing means will get into the opening. Excessive sealing means in the opening could cause the parts of the cooling body that protrude into the opening to be moistened with sealing means. Thus the collar, in cooperation with the groove, to some extent specifies a defined flow direction for some of the sealing means.

If the groove surrounds a pedestal which protrudes into the opening, then component tolerances can be managed more generously, since because of the embodiment of a pedestal, a flow resistance for the sealing means in the opening is increased, and here as well, the pedestal, with its relatively large surface area, acts as a flow regulator (throttle restriction). The profiling of the collar is advantageous in this case also because as a result the sealing means cannot get onto a surface of the pedestal that protrudes into the opening. This surface is intended to receive either a substrate holder (LBS), or a substrate directly, which acts as a holder for electronic components.

In a further feature, it is provided that the groove, in the region of its opening, has a widened portion, which extends on the side facing away from the pedestal. This widened portion of the groove has the advantage that excess sealing means, for instance, that is forced by the collar out of the bottom of the groove into upper regions of the groove, is received there without moistening a contact face between the cooling body and the housing. Hence this widened portion is a provision for assuring the tightness between the housing and the cooling body.

In a further feature of the invention, it is provided that the pedestal protrudes past a contact face of the cooling body on the housing. This has the advantage that despite the mounting of the cooling body from the outside of the housing, a mounting face for the substrate holder or the substrate continues to be obtained that is located relatively close to the bottom of the interior of the housing. This makes the mounting of the LBS with the substrate, or of the substrate alone, on the pedestal easier.

### DRAWINGS

In the drawings, exemplary embodiments of an electric device of the invention are shown.

FIG. 1 shows a cross section through the housing and its interior and through the cooling body joined to the housing;

FIG. 2 in a fragmentary view shows a variant of the design of the groove in the cooling body.

### DESCRIPTION

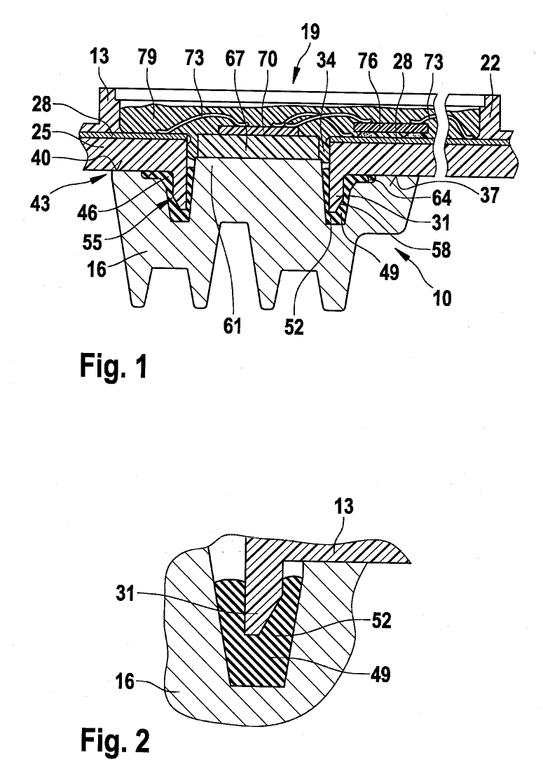

In FIG. 1, a cross section through an electric device 10 with a housing 13 and a cooling body 16 is shown in fragmentary form. The housing 13 has a housing interior 19, which is surrounded by a wall 22. The housing interior 19 is further defined by a bottom 25. The surface of the bottom 25 is formed in part by the surface of conductors 28 located in the housing 13. Toward one side of the bottom 25, the housing 13 has the housing interior 19, which is defined by the wall 22, and on the other side, on the other side of the bottom 25, the housing has a collar 31, which lengthens an opening 34 provided in the bottom 25 or defines it beyond the bottom 25 over the entire circumference of the opening 34. The surface of the housing part 13 facing away from the housing interior 19 forms a contact face 37 for the cooling body 16. The cooling body 16 rests with its contact face 40 on this contact face 37 of the housing 13. Between the cooling body 16 and the housing 13, a seam 43 is formed, which is initially formed between the contact faces 37 and 40. This seam 43 changes over into an interstice 46 that is formed by a groove 49 in the cooling body 16 and by the collar 31 that is located in the groove 49. A sealing means 52 is introduced into this groove 49 and closes the seam 43 between the collar 31 and the groove 49 in at least fluid-tight fashion.

Thus an electric device 10 with a housing 13 and a cooling body 16 is provided, and the cooling body 16 is secured to the housing 13. Between the cooling body 16 and the separate housing 13 is a seam 43, which at least partially comprises a collar 33, surrounding an opening 34, and a groove 49, receiving the collar. Between the collar 31 and the groove 49 is a sealing means 52, which closes the seam 43 in at least fluid-tight fashion.

The collar 31 is profiled in such a way that a curvature 55 is on a side of the collar 31 facing away from the opening 34. Alternatively, the collar 31 can also be designed such that the collar 31, for instance of rectangular shape, is designed in the form of the jacket of a truncated pyramid on the end oriented toward the groove 49. In other words, on its outer side facing away from the opening 34, the collar 31 has a chamfer or bevel 58.

The groove 49 surrounds a pedestal 61, which protrudes into the opening 34. It is provided that the pedestal 61 protrudes past a contact face 40 of the cooling body 16.

The groove 49, in the region of its opening, has a widened portion 64, which extends on the side facing away from the pedestal 61. In the cases in which the sealing means for production reasons sometimes needs to be more generously sized, this widened portion 64, as shown in FIG. 1, receives the sealing means 52.

In FIG. 2, a simpler variant of the groove 49 is shown. Here, the groove 49 has no widened portion 64, so that the sealing means 52 is located solely in a relatively slender groove 49.

It is furthermore provided that an LBS 67 is mounted on the pedestal 61 and holds a first substrate 70. This substrate 70, for instance an electronic regulator, is electrically conductively connected, for instance to the conductors 28, via bond wires 73. It can furthermore be provided that a second substrate 76 is located in the housing interior 19 and is connected via bond wires 73 both to conductors 28 and to the first substrate 70. It is provided that the two substrates 70 and 76 as well as the bond wires 73 are covered by a potting composition 79.

1. An electric device (10), having a housing (13) and a cooling body (16), the cooling body (16) being secured to the housing (13), characterized in that between the cooling body (16) and the separate housing (13) is a seam (43), which at least partially comprises a collar (33), surrounding an opening (34), and a groove (49), receiving the collar, and between the collar (31) and the groove (49) is a sealing means (52), which closes the seam (43) in at least fluid-tight fashion.

2. The electric device as defined by claim 1, characterized in that the collar (31) is profiled in such a way that a curvature (55) is on a side of the collar (31) facing away from the opening (34).

3. The electric device as defined by claim 1, characterized in that the groove (49) surrounds a pedestal (61), which protrudes into the opening (34).

4. The electric device as defined by claim 3, characterized in that the groove (49), in the region of its opening, has a widened portion (64), which extends on the side facing away from the pedestal (61).

5. The electric device as defined by claim 4, characterized in that the widened portion (64) receives sealing means (52).

6. The electric device as defined by claim 3, characterized in that the pedestal (61) protrudes past a contact face (40) of the cooling body (16).
